(19) United States
(12) Patent Application Publication
(10) Pub. No.: US 2026/0129778 A1
(43) Pub. Date: May 7, 2026

(54) HOUSING AND ELECTRONIC DEVICE COMPRISING SAME

(71) Applicant: SAMSUNG ELECTRONICS CO., LTD., Suwon-si (KR)

(72) Inventors: Taehyun SONG, Suwon-si (KR); Jongwan JEONG, Suwon-si (KR)

(21) Appl. No.: 19/437,588

(22) Filed: Dec. 31, 2025

Related U.S. Application Data
(63) Continuation of application No. PCT/KR2024/007891, filed on Jun. 10, 2024.

(30) Foreign Application Priority Data
Jul. 3, 2023 (KR) 10-2023-0086009
Oct. 10, 2023 (KR) 10-2023-0134546

(51) Int. Cl. H05K 5/03

(52) U.S. Cl. CPC H05K 5/03

(57) ABSTRACT

In an electronic device including a housing according to an embodiment of the present disclosure, the housing may include: a substrate; a color layer which is disposed on the substrate and in which a first material having a first refractive index and a second material having a second refractive index greater than the first refractive index are alternately laminated; a first support layer which is disposed on the color layer; and a reflective layer which is disposed on the first support layer and in which a third material having a third refractive index and a fourth material having a fourth refractive index greater than the third refractive index are alternately laminated. The difference between the first refractive index and the second refractive index is greater than the difference between the third refractive index and the fourth refractive index, and the third refractive index is greater than the first refractive index.

This application is a continuation application, claiming priority under § 365(c), of International Application No. PCT/KR2024/007891, filed on Jun. 10, 2024, which is based on and claims the benefit of Korean patent application number 10-2023-0086009, filed on Jul. 3, 2023, and Korean patent application number 10-2023-0134546, filed on Oct. 10, 2023, the disclosures of which are incorporated by reference herein in their entireties.

### BACKGROUND

### Field

An embodiment disclosed herein relates to a housing and an electronic device including the same.

### Description of the Related Art

Thanks to remarkable advancements in information and communication technology and semiconductor technology, the distribution and use of various electronic devices are rapidly increasing. In particular, recent electronic devices are being developed to be portable and capable of communication.

The term “electronic device” may refer to a device that performs a specific function according to an installed program, such as a home appliance, an electronic notebook, a portable multimedia player, a mobile communication terminal, a tablet PC, an image/audio device, a desktop/laptop computer, or a vehicle navigation system. For example, such electronic devices may output stored information as sound or images. As the integration level of electronic devices increases and ultra-high-speed, large-capacity wireless communication becomes widespread, various functions may be incorporated into a single electronic device such as a mobile communication terminal. For example, in addition to communication functions, functions such as entertainment functions like games, multimedia functions like music/video playback, communication and security functions for mobile banking, and functions like scheduling or an electronic wallet are being incorporated into a single electronic device. Such electronic devices are being miniaturized such that a user can conveniently carry them. As the carrying and use of miniaturized or thinned mobile devices, such as smartphones, becomes commonplace, user demands for the exterior design of mobile devices may become more sophisticated and diversified.

The above-described information may be provided as related art for the purpose of aiding understanding of the disclosure. No claim or determination is made as to whether any of the foregoing constitutes prior art related to the disclosure.

### SUMMARY

According to an embodiment of the disclosure, in an electronic device including a housing, the housing may include a substrate, a color layer disposed above the substrate, wherein a first material having a first refractive index and a second material having a second refractive index greater than the first refractive index are alternately stacked, a first support layer disposed on the color layer, and a reflective layer disposed on the first support layer, wherein a third material having a third refractive index and a fourth material having a fourth refractive index greater than the third refractive index are alternately stacked. A difference between the first refractive index and the second refractive index may be greater than a difference between the third refractive index and the fourth refractive index. The third refractive index may be greater than the first refractive index.

According to an embodiment of the disclosure, in an electronic device including a housing, the housing may include a substrate, a color layer disposed above the substrate, wherein a first material having a first refractive index and a second material having a second refractive index greater than the first refractive index are alternately stacked, a first support layer disposed on the color layer, and a reflective layer disposed on the first support layer, wherein a third material having a third refractive index and a fourth material having a fourth refractive index greater than the third refractive index are alternately stacked. A color coordinate value of the color layer may be 5 or more. A reflectance of the reflective layer may be 10% or greater.

### BRIEF DESCRIPTION OF THE DRAWINGS

FIG. 1 is a block diagram of an electronic device in a network environment, according to an embodiment disclosed herein.

FIG. 2 is a perspective view illustrating a front side of an electronic device according to an embodiment disclosed herein.

FIG. 3 is a perspective view illustrating a rear side of the electronic device of FIG. 2 according to an embodiment disclosed herein.

FIG. 4A is an exploded perspective view illustrating a front side of the electronic device of FIG. 2, according to an embodiment disclosed herein.

FIG. 4B is an exploded perspective view illustrating a rear side of the electronic device of FIG. 2, according to an embodiment disclosed herein.

FIG. 5 is a cross-sectional view illustrating a portion of the housing of FIG. 3, according to an embodiment disclosed herein, taken along line A-A', and an enlarged cross-sectional view illustrating a color layer and a reflective layer.

FIG. 6 is a cross-sectional view illustrating a portion of the housing, according to an embodiment disclosed herein.

FIG. 7 illustrates a change in color shift due to scratches of the housing according to an embodiment disclosed herein, under an abrasion resistance evaluation using steel wool.

FIG. 8 illustrates scratch visibility of the housing according to an embodiment disclosed herein, after a scratch test using a Mohs hardness tester, under a condition in which ambient light is reflected laterally.

### DETAILED DESCRIPTION

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described herein.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel”means approximately or actually parallel.

The term “adjacent” is used to describe the relative positions of various components. The term may refer to a directly adjacent relationship between components but is not necessarily limited or intended to mean that the components are directly adjacent each other. The term may mean that the components are situated in respective regions that are directly adjacent and the components may therefore be mutually proximal and be separated by a gap. For example, the term “adjacent” or “adjacent to,” as used herein, may include “next to,” “adjoining,” “in contact with,” or “in proximity to.”

As used in connection with an embodiment of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

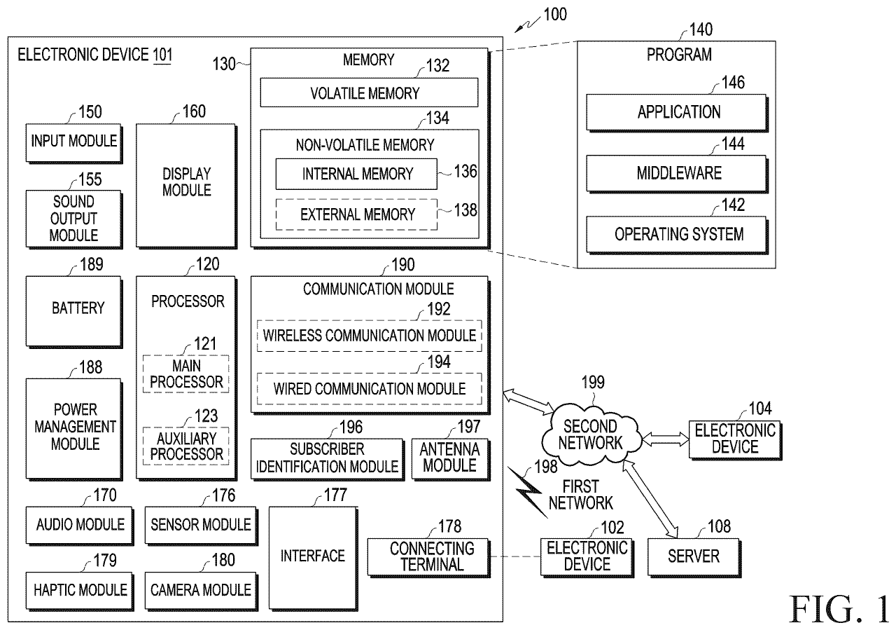

FIG. 1 is a block diagram illustrating an electronic device in a network environment according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. In an example in which the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices (e.g., electronic device 102, electronic device 104, or server 108). For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

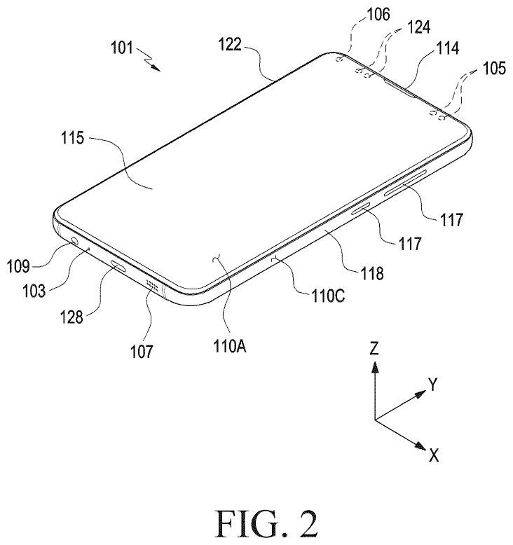

FIG. 2 is a perspective view illustrating a front side of an electronic device 101 according to various embodiments disclosed herein.

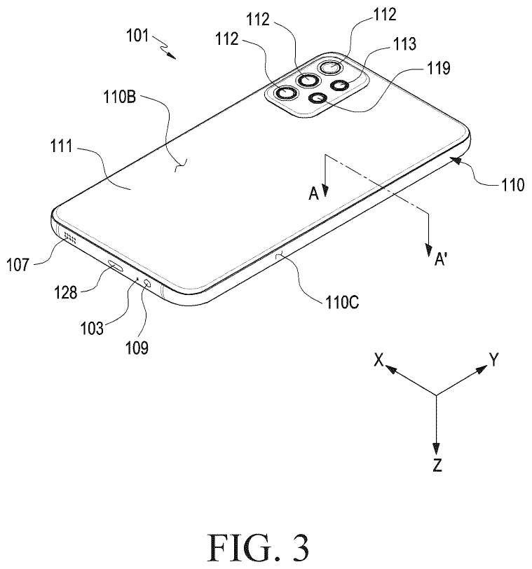

FIG. 3 is a perspective view illustrating a rear side of the electronic device 101 of FIG. 2 according to an embodiment disclosed herein.

Referring to FIGS. 2 and 3, the electronic device 101 (e.g., the electronic device 101 in FIG. 1) according to an embodiment may include a housing 110 including a first surface (or the front surface) 110A, a second surface (or the rear surface) 110B, and a side surface 110C surrounding the space between the first surface 110A and the second surface 110B. In an embodiment (not illustrated), the housing 110 may refer to a structure that forms at least a portion of the first surface 110A of FIG. 2, and the second surface 110B and the side surface 110C of FIG. 3.

According to an embodiment, at least a portion of the first surface 110A may be defined by a front surface plate 122 (e.g., a glass plate or a polymer plate including various coating layers) which is substantially transparent. The second surface 110B may be defined by a rear surface plate 111 which is substantially opaque. The rear surface plate 111 may be formed of, for example, coated or colored glass, ceramic, polymer, metal (e.g., aluminum, stainless steel (STS), or magnesium), or a combination of two or more of these materials. The side surface 110C may be defined by a side surface structure (or a “side surface bezel structure”) 118 coupled to the front surface plate 122 and the rear surface plate 111 and including metal and/or polymer. In an embodiment, the rear surface plate 111 and the side surface structure 118 may be integrally formed and may include the same material (e.g., a metal material such as aluminum).

According to an embodiment, the front surface plate 122 may include one or more areas curved and extending seamlessly from at least a portion of an edge toward the rear surface plate 111. For example, the front surface plate 122 (or the rear surface plate 111) may include a single one of the areas curved and extending toward the rear surface plate 111 (or the front surface plate 122), at one side edge of the first surface 110A. According to an embodiment, the front surface plate 122 or the rear surface plate 111 may have a substantially flat plate shape, and for example, may not include a curved and extending area. In an example in which the front surface plate 122 or the rear surface plate 111 includes a curved and extending area, the thickness of the electronic device 101 at the portion where the curved extension area is included may be smaller than the thickness at other portions.

According to an embodiment, the electronic device 101 may include at least one of a display 115, an audio module (e.g., a microphone hole 103, an external speaker hole 107, and a call receiver hole 114), a sensor module (e.g., a first sensor module 124, a second sensor module (not illustrated), and a third sensor module 119), a camera module (e.g., a first camera device 105, a second camera device 112, and a flash 113), key input devices 117, a light-emitting element 106, and connector holes (e.g., a first connector hole 128 and a second connector hole 109). In an embodiment, at least one of the components (e.g., the key input devices 117 or the light-emitting element 106) may be omitted from the electronic device 101 or other components may be additionally included.

The display 115 may output a screen or may be visually exposed through, for example, a substantial portion of the first surface 110A (e.g., the front surface plate 122). In an embodiment, at least a portion of the display 115 may be visually exposed through the front surface plate 122 forming the first surface 110A or through a portion of the side surface 110C. In an embodiment, a corner of the display 115 may be formed to be substantially the same as the outer shape of the front surface plate 122 adjacent thereto. In an embodiment (not illustrated), in order to enlarge the visually exposed area of the display 115, the gap between the periphery of the display 115 and the periphery of the front surface plate 122 may be formed to be substantially the same.

According to an embodiment, recesses or openings may be provided in some portions of the screen display area of the display 115, and one or more of an audio module (e.g., the call receiver hole 114), a sensor module (e.g., the first sensor module 124), a camera module (e.g., the first camera device 105), and a light-emitting element 106 may be aligned with the recesses or the openings. In an embodiment (not illustrated), the rear surface of the screen display area of the display 115 may include at least one of an audio module (e.g., the call receiver hole 114), a sensor module (e.g., the first sensor module 124), a camera module (e.g., the first camera device 105), a fingerprint sensor (not illustrated), and a light-emitting element 106. In an embodiment (not illustrated), the display 115 may be coupled to or disposed adjacent to a touch-sensitive circuit, a pressure sensor capable of measuring a touch intensity (pressure), and/or a digitizer configured to detect a magnetic field-type stylus pen.

According to an embodiment, the audio modules may include a microphone hole 103 and speaker holes (e.g., the external speaker hole 107 and the call receiver hole 114). A microphone configured to acquire external sound may be disposed inside the microphone hole 103, and in an embodiment, multiple microphones may be disposed to detect the direction of sound. The speaker holes may include the external speaker hole 107 and the call receiver hole 114. In an embodiment, the speaker holes (e.g., the external speaker hole 107 and the call receiver hole 114) and the microphone hole 103 may be implemented as a single hole, or a speaker may be included without the speaker holes (e.g., the external speaker hole 107 and the call receiver hole 114) (e.g., a piezo speaker).

According to an embodiment, the sensor modules may generate electrical signals or data values corresponding to an internal operating state or an external environmental state of the electronic device 101. The sensor modules may include, for example, a first sensor module 124 (e.g., a proximity sensor) and/or a second sensor module (not illustrated) (e.g., a fingerprint sensor) disposed on the first surface 110A of the housing 110, and/or a third sensor module 119 disposed on the second surface 110B of the housing 110. The second sensor module (not illustrated) (e.g., a fingerprint sensor) may be disposed not only on the first surface 110A (e.g., the display 115) of the housing 110, but also on the second surface 110B or the side surface 110C of the housing 110. The electronic device 101 may further include at least one of, for example, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor (e.g., a first sensor module 124).

According to an embodiment, the camera module may include a first camera device 105 disposed on the first surface 110A of the electronic device 101, and a second camera device 112 and/or a flash 113 disposed on the second surface 110B of the electronic device 101. The camera devices (e.g., the first camera device 105 and the second camera device 112) may include one or more lenses, an image sensor, and/or an image signal processor. The flash 113 may include, for example, a light-emitting diode or a xenon lamp. In an embodiment, one or more lenses (e.g., an infrared camera lens, a wide-angle lens, and a telephoto lens) and image sensors may be disposed on one surface of the electronic device 101. In an embodiment, the flash 113 may emit infrared light, and the infrared light emitted by the flash 113 and reflected by a subject may be received through the third sensor module 119. The electronic device 101 or a processor (e.g., the processor 120 in FIG. 1) of the electronic device 101 may detect depth information of the subject based on a time point when the infrared rays are received by the third sensor module 119.

According to an embodiment, the key input devices 117 may be disposed on the side surface 110C of the housing 110. In an embodiment, the electronic device 101 may not include some or all of the above-described key input devices 117, and a key input device 117 not included may be implemented in another form, such as a soft key, on the display 115. In an embodiment, the key input devices may include a sensor module disposed on the second surface 110B of the housing 110.

According to an embodiment, the light-emitting element 106 may be disposed on, for example, the first surface 110A of the housing 110. The light-emitting elements 106 may provide, for example, the state information of the electronic device 101 in the form of light. In an embodiment, the light-emitting element 106 may provide a light source that is linked to the operation of, for example, the camera module (e.g., the first camera device 105). The light-emitting elements 106 may include, for example, an LED, an IR LED, and a xenon lamp.

According to an embodiment, the connector holes (e.g., a first connector hole 128 and a second connector hole 109) may include a first connector hole 128 configured to accommodate a connector (e.g., a USB connector) configured to transmit/receive power and/or data with an external electronic device (e.g., the electronic device 102 in FIG. 1), and/or a second connector hole (e.g., an earphone jack) 109 configured to accommodate a connector configured to transmit/receive an audio signal with an external electronic device.

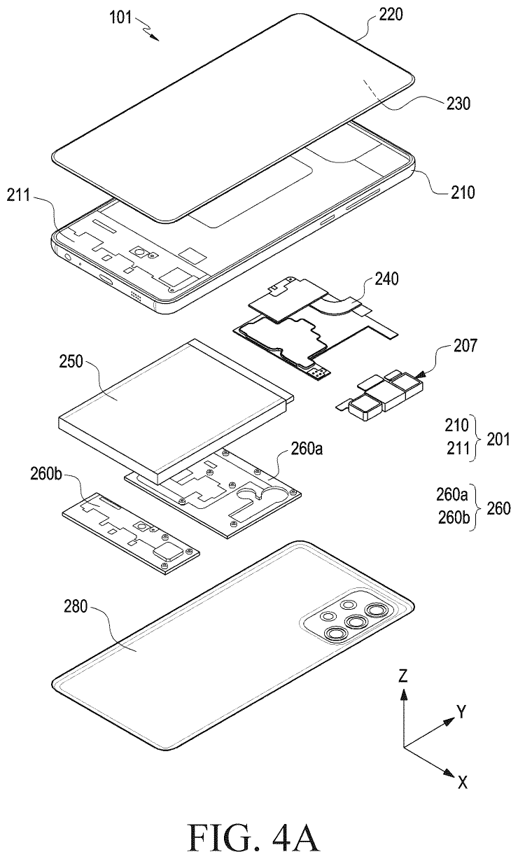

FIG. 4A is an exploded perspective view illustrating a front side of the electronic device 101 of FIG. 2, according to an embodiment disclosed herein.

FIG. 4B is an exploded perspective view illustrating a rear side of the electronic device 101 of FIG. 2, according to an embodiment disclosed herein.

Referring to FIGS. 4A and 4B, the electronic device 101 (e.g., the electronic device 101 of FIG. 1, 2, or 3) may include a side surface structure 210, a first support member 211 (e.g., a bracket), a front surface plate 220 (e.g., the front surface plate 122 of FIG. 2), a display 230 (e.g., the display 115 of FIGS. 2 and 3), a printed circuit board (or a substrate assembly) 240, a battery 250, a second support member 260 (e.g., a rear case), an antenna, a camera assembly 207, and a rear surface plate 280 (e.g., the rear surface plate 111 of FIG. 3).

According to an embodiment, at least one of the components (e.g., the first support member 211 or the second support member 260) may be omitted from the electronic device 101 or may additionally include other components. At least one of the components of the electronic device 101 may be the same as or similar to at least one of the components of the electronic device 101 illustrated in FIG. 2 or FIG. 3, and redundant descriptions are omitted below.

According to an embodiment, the first support member 211 may be disposed inside the electronic device 101 to be connected to the side surface structure 210 or may be integrated with the side surface structure 210. The first support member 211 may be formed of, for example, a metal material and/or a non-metal (e.g., polymer) material. In an example in which at least partially formed of a metal material, a portion of the side surface structure 210 or the first support member 211 may serve as an antenna. The first support member 211 may include one surface to which the display 230 is coupled and the other surface to which the printed circuit board 240 is coupled. A processor (e.g., the processor 120 in FIG. 1), memory (e.g., the memory 130 in FIG. 1), and/or an interface (e.g., the interface 177 in FIG. 1) may be mounted on the printed circuit board 240. The processor may include one or more of, for example, a central processing unit, an application processor, a graphics processing unit, an image signal processor, a sensor hub processor, or a communication processor.

According to an embodiment, the first support member 211 and the side surface structure 210 may be combined to be referred to as a front case or a housing 201. According to an embodiment, the housing 201 may be generally understood as a structure for accommodating, protecting, or positioning the printed circuit board 240 or the battery 250. In an embodiment, it may be understood that the housing 201 includes structures capable of being visually or tactually recognized by a user in the exterior of the electronic device 101, such as the side surface structure 210, the front surface plate 220, and/or the rear surface plate 280. In an embodiment, the “front surface or rear surface of the housing 201” may be understood as the first surface 110A in FIG. 2 or the second surface 110B in FIG. 3. In an embodiment, the first support member 211 may be disposed between the front surface plate 220 (e.g., the first surface 110A in FIG. 2) and the rear surface plate 280 (e.g., the second surface 110B in FIG. 3) and may serve as a structure for arranging electrical/electronic components, such as a printed circuit board 240 or a camera assembly 207.

According to an embodiment, the display 230 may include a display panel 231 and a flexible printed circuit board 233 extending from the display panel 231. The flexible printed circuit board 233 may be understood, for example, to be electrically connected to the display panel 231 while being disposed at least partially on the rear surface of the display panel 231. In an embodiment, reference numeral “231” may be understood as denoting a protective sheet disposed on the rear surface of the display panel. For example, unless otherwise classified in the following detailed description, the protective sheet may be understood as being a portion of the display panel 231. In an embodiment, the protective sheet may function as a buffer structure (e.g., a low-density elastic material such as a sponge) absorbing an external force or an electromagnetic shield structure (e.g., a copper sheet (CU sheet)). According to an embodiment, the display 230 may be disposed on the inner surface of the front surface plate 220 and may include a light-emitting layer to output a screen through at least a portion of the first surface 110A of FIG. 2 or the front surface plate 220. As mentioned above, the display 230 may output a screen through substantially the entire area of the first surface 110A of FIG. 2 or the front surface plate 220.

According to an embodiment, the memory may include, for example, volatile memory or non-volatile memory.

According to an embodiment, the interface may include, for example, a high-definition multimedia interface (HDMI), a universal serial bus (USB) interface, an SD card interface, and/or an audio interface. For example, the interface may electrically or physically connect the electronic device 101 to an external electronic device, and may include a USB connector, an SD card/MMC connector, or an audio connector.

According to an embodiment, the second support member 260 may include, for example, an upper support member 260a and a lower support member 260b. In an embodiment, the upper support member 260a may be disposed to surround the printed circuit board 240 together with a portion of the first support member 211. A circuit device implemented in the form of an integrated circuit chip (e.g., a processor, a communication module, or memory) or various electrical/electronic components may be disposed on the printed circuit board 240, and in some embodiments, the printed circuit board 240 may be provided with an electromagnetic shielding environment from the upper support member 260a. In an embodiment, the lower support member 260b may serve as a structure for positioning electric/electronic components such as a speaker module and an interface (e.g., a USB connector, an SD card/MMC connector, or an audio connector). In an embodiment, electrical/electronic components, such as a speaker module and an interface (e.g., a USB connector, an SD card/MMC connector, or an audio connector), may be disposed on an additional printed circuit board (not illustrated). For example, the lower support member 260b may be disposed to surround the additional printed circuit board together with another portion of the first support member 211. The speaker module or interface disposed on the additional printed circuit board (not illustrated) or the lower support member 260b may be arranged to correspond to the audio module of FIG. 2 (e.g., the microphone hole 103 or the speaker holes (e.g., the external speaker hole 107 and the call receiver hole 114)) or the connector holes (e.g., the first connector hole 128 and the second connector hole 109).

According to an embodiment, the battery 250 may serve as a device that supplies power to at least one component of the electronic device 101, and may include, for example, a non-rechargeable primary cell, a rechargeable secondary cell, or a fuel cell. At least a portion of the battery 250 may be disposed on substantially the same plane as, for example, the printed circuit board 240. The battery 250 may be integrally disposed inside the electronic device 101 or may be detachably disposed relative to the electronic device 101.

Although not illustrated, the antenna may include a conductor pattern implemented on the surface of the second support member 260 through, for example, a laser direct structuring method. In an embodiment, the antenna may include a printed circuit pattern provided on the surface of a thin film, and the thin film-type antenna may be disposed between the rear surface plate 280 and the battery 250. The antenna may include, for example, a near-field communication (NFC) antenna, a wireless charging antenna, and/or a magnetic secure transmission (MST) antenna. The antenna may, for example, perform near-field communication with an external device, or wirelessly transmit and receive power for charging. In an embodiment, an antenna structure may be configured with a portion or a combination of the side surface structure 210 and/or the first support member 211.

According to an embodiment, the camera assembly 207 may include at least one camera module. Inside the electronic device 101, the camera assembly 207 may receive at least some of light incident through optical holes or camera windows 212, 213, and 219. In an embodiment, the camera assembly 207 may be disposed on the first support member 211 at a position adjacent to the printed circuit board 240. In an embodiment, the camera modules of the camera assembly 207 may be generally aligned with one of the camera windows 212, 213, and 219, and may be at least partially surrounded by the second support member 260 (e.g., the upper support member 260a).

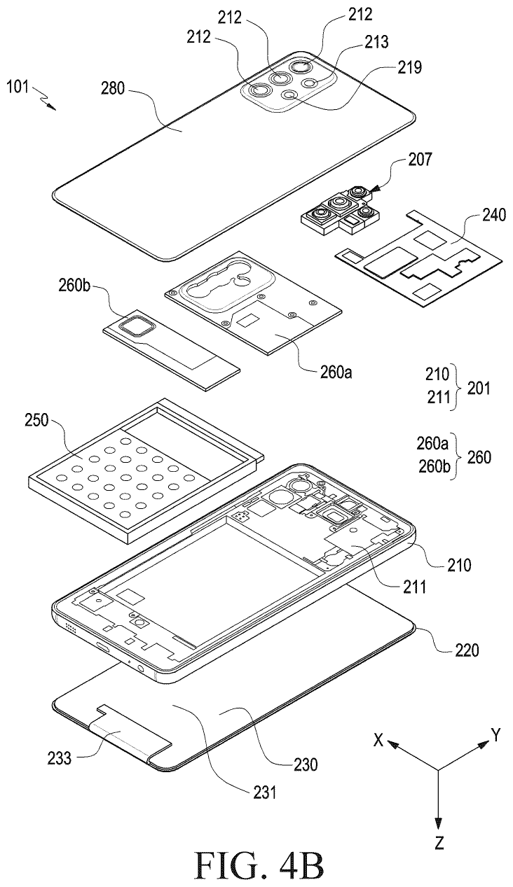

FIG. 5 is a cross-sectional view illustrating a portion of the housing 300 of FIG. 3, according to an embodiment disclosed herein, taken along line A-A′, and an enlarged cross-sectional view illustrating a color layer 330 and a reflective layer 350.

Referring to FIG. 5, the housing 300 of the electronic device 101 may include a substrate 310, a buffer layer 320, a color layer 330, a first support layer 340, a reflective layer 350, a second support layer 360, and a protective coating layer 370. The configuration of the housing 300 in FIG. 5 may be wholly or partly the same as the configuration of the housing 201 in FIGS. 4A and 4B. The structure of FIG. 5 may be selectively combined with the structures of FIGS. 2 to 4B.

According to an embodiment, the housing 300 may be, when referring to FIGS. 2 and 3, the second surface (or the rear surface) (e.g., the second surface 110B of FIG. 2). The housing 300 may substantially correspond to the rear surface plate (e.g., the rear surface plate 111 of FIG. 2) when referring to FIGS. 2 and 3; however, the housing 300 is not limited to the rear surface according to FIGS. 2 to 3, and may be variously modified in design. The housing 300 may be formed of, for example, coated or dyed glass, ceramic, polymer, metal (e.g., aluminum, stainless steel (STS), or magnesium), or a combination of at least two of the above materials.

According to an embodiment, the housing 300 may include the substrate 310 configured to protect internal components of the electronic device (the electronic device 101 of FIG. 2) from external impact. According to an embodiment, the substrate 310 may be a transparent material to allow light to pass therethrough. For example, the substrate 310 may be formed of glass, a polymer film, or a polymer plastic. For example, the substrate 310 may be heat-treated and chemically reinforced glass. For example, the polymer film of the substrate 310 may include at least one of polyimide, polyethylene terephthalate (PET), or another polymer material. According to an embodiment, since the substrate 310 is optically transparent, aesthetic effects according to the color and/or texture of each of multiple layers constituting the housing 300 may be overlapped and appear in combination. According to an embodiment, the substrate 310 may be an opaque material. For example, to provide a metallic surface having gloss and scratch resistance corresponding to an anodizing process, a metal including aluminum may be used as the substrate 310.

According to an embodiment, the buffer layer 320 may be disposed on the substrate 310. The buffer layer 320 may be disposed between the substrate 310 and an optical coating layer (e.g., the color layer 330) to increase adhesion between the substrate 310 and the optical coating layer (e.g., the color layer 330). According to an embodiment, the buffer layer 320 may be formed of a material for stable adhesion to the substrate 310. In an example in which the substrate 310 is glass, the buffer layer 320 may include silica (SiO₂). In an example in which the substrate 310 is an aluminum substrate 310 free of an oxide film, the buffer layer 320 may include at least one of an aluminum (Al) metal film, an aluminum oxynitride (AlON) metal film, or an aluminum oxide (Al₂O₃) metal film. In an example in which the substrate 310 has an anodized surface on which an oxide film is formed, the buffer layer 320 may include aluminum oxide (Al₂O₃). In an example in which the substrate 310 is stainless steel, the buffer layer 320 may include at least one of zirconium (Zr) or titanium (Ti). In an example in which the substrate 310 is a thermosetting injection-molded article, the buffer layer 320 may include a clear coat including, for example, an acrylic resin or a polyester resin. On the buffer layer 320 including the clear coat, a base layer (not illustrated) including silica (SiO₂) may optionally be further included.

According to an embodiment, the housing 300 may include the color layer 330 and the reflective layer 350 disposed on the substrate 310. According to an embodiment, each of the color layer 330 and the reflective layer 350 may be formed by alternately stacking two different materials having different refractive indices. As light incident from the outside passes through the color layer 330 and the reflective layer 350, constructive or destructive interference of wavelengths may occur due to the difference in refractive indices between the different materials, and the reflectance or color tone expressed by such constructive or destructive interference of wavelengths may be visually revealed to the outside. According to an embodiment, the color layer 330 and the reflective layer 350 may be formed of a transparent material to allow light to pass therethrough. According to an embodiment, the color layer 330 and the reflective layer 350 may be manufactured by a deposition method. For example, the color layer 330 and the reflective layer 350 may be manufactured by a vapor deposition method.

According to an embodiment, a deposition process may be defined as a process of coating the surface of an object with a thin solid film of several nanometers to several micrometers in thickness using metallic or compound particles in a gaseous state. For example, as light passes through interfaces of each layer constituting the transparent housing 300, the light may be transmitted or reflected depending on the component and/or band of the light. Through the effect of overlapping (or destructive or constructive interference) among components having different optical paths, the optical structure may be designed to achieve a specific color or a specific reflectance (gloss).

According to an embodiment, a vapor deposition method may be classified into chemical vapor deposition (CVD) and physical vapor deposition (PVD). According to an embodiment, a first vapor deposition process (S1), a second vapor deposition process (S2), and a third vapor deposition process (S3) may be at least one of chemical vapor deposition (CVD) and physical vapor deposition (PVD). Chemical vapor deposition (CVD) may be defined as a method of forming a metal thin film by applying heat to a gaseous metal source and a reactive gas or by turning the gaseous metal source and the reactive gas into plasma to generate highly reactive radicals, and inducing a chemical reaction on a high-temperature substrate 310 (e.g., the substrate 310). Physical vapor deposition (PVD) may be defined as a method in which energy applied to a desired metal or compound is converted into kinetic energy such that the material is transferred and deposited on the substrate 310 (e.g., the substrate 310) to form a thin film.

According to an embodiment, by alternately stacking materials having a relatively large difference in refractive indices, the color layer 330 may exhibit a color tone having a high color coordinate value due to optical interference.

According to an embodiment, the color layer 330 may include a first material 331 having a first refractive index and a second material 332 having a second refractive index greater than the first refractive index, which are alternately stacked. For example, referring to FIG. 5, the color layer 330 may include a (1-1)^{th} material 331a having a first refractive index, a (2-1)^{th} material 332a disposed on the (1-1)^{th} material 331a and having a second refractive index, a (1-2)^{th} material 331b disposed on the (2-1)^{th} material 332a and having the first refractive index, and a (2-2)^{th} material 332b disposed on the (1-2)^{th} material 331b and having the second refractive index. For example, a cycle in which the first material 331 and the second material 332 are alternately stacked may range from two times to ten times. For example, the cycle in which the first material 331 and the second material 332 are alternately stacked may preferably be five times. For example, a thickness t1 of each material constituting the color layer 330 (e.g., the (1-1)^{th} material 331a, the (2-1)^{th} material 332a, the (1-2)^{th} material 331b, and the (2-2)^{th} material 332b) may range from about 5 nm to about 30 nm. For example, the color layer 330 may be described as a structural color layer.

According to an embodiment, a difference in refractive indices of the materials constituting the color layer 330 may be greater than a difference in refractive indices of the materials constituting the reflective layer 350. For example, a difference between the first refractive index and the second refractive index may be greater than a difference between a third refractive index and a fourth refractive index. For example, the difference between the first refractive index and the second refractive index may be about 0.4 or more. For example, the difference between the first refractive index and the second refractive index may be about 0.5 or more. For example, the first refractive index may range from about 1.4 to about 1.6 (which may be defined as a “low refractive index”), and the first material 331 having the first refractive index may include silica (SiO₂). For example, the second refractive index may range from about 2.0 to about 2.5 (which may be defined as a “high refractive index”), and the second material 332 having the second refractive index may include silicon nitride (SiN). The color layer 330 may exhibit a color tone having a high color coordinate value due to optical interference, by alternately stacking materials having relatively large differences in refractive indices. According to an embodiment, the color coordinate value of the color layer 330 may be 5 or more (in the CIELAB color coordinate space, color coordinate=√(a²+b²)).

According to an embodiment, the reflective layer 350 may exhibit optical properties of high reflectance by alternately stacking materials having relatively high refractive indices. For example, the reflective layer 350 may be described as a reflective layer for luminance.

According to an embodiment, the reflective layer 350 may include a third material 351 having a third refractive index and a fourth material 352 having a fourth refractive index greater than the third refractive index, which are alternately stacked. For example, the reflective layer 350 may include a (3-1)^{th} material 351a having the third refractive index, a (4-1)^{th} material 352a disposed on the (3-1)^{th} material 351a and having the fourth refractive index, a (3-2)^{th} material 351b disposed on the (4-1)^{th} material 352a and having the third refractive index, and a (4-2)^{th} material 352b disposed on the (3-2)^{th} material 351b and having the fourth refractive index. For example, a cycle in which the third material 351 and the fourth material 352 are alternately stacked may range from two times to ten times. For example, the cycle in which the third material 351 and the fourth material 352 are alternately stacked may preferably be five times. For example, a thickness t2 of each material constituting the reflective layer 350 (e.g., the (3-1)^{th} material 351a, the (4-1)^{th} material 352a, the (3-2)^{th} material 351b, and the (4-2)^{th} material 352b) may range from about 5 nm to about 50 nm.

According to an embodiment, an average refractive index of the materials constituting the reflective layer 350 may be greater than an average refractive index of the materials constituting the color layer 330. According to an embodiment, the third refractive index of the third material 351 constituting the reflective layer 350 may be greater than the first refractive index of the first material 331 constituting the color layer 330. For example, the third refractive index may range from about 1.65 to about 2.0 (which may be defined as a “medium refractive index”), and the third material 351 having the third refractive index may include silicon oxynitride (SiON). For example, the fourth refractive index may range from about 2.0 to about 2.5 (which may be defined as a “high refractive index”), and the fourth material 352 having the fourth refractive index may include silicon nitride (SiN). For example, in order to prevent or mitigate the occurrence of chromatic reflective gloss in the reflective layer 350 due to the optical interference effect of the third material 351 and the fourth material 352, a difference between the third refractive index and the fourth refractive index may be about 0.3 or less. The reflective layer 350 may have high reflectance by alternately stacking materials having relatively high refractive indices. According to an embodiment, the reflectance of the reflective layer 350 may be about 7% or more. For example, the reflectance of the reflective layer 350 may be about 10% or more.

According to an embodiment, the color layer 330 may be disposed closer to the substrate 310 than the reflective layer 350. According to an embodiment, as the color layer 330 is disposed farther from the outer surface than the reflective layer 350, the color layer 330 may be less likely to be damaged by scratches. Even if a scratch occurs, since the color layer 330 is less likely to be damaged, the visibility of color degradation due to scratches may be reduced.

According to an embodiment, the color layer 330 and the reflective layer 350 may be disposed to be physically separated. According to an embodiment, a first support layer 340 may be disposed between the color layer 330 and the reflective layer 350. According to an embodiment, the first support layer 340 may be disposed on the color layer 330. For example, a thickness t3 of the first support layer 340 may range from about 80 nm to about 500 nm. For example, in order to provide hardness equal to or greater than the hardness of the substrate 310, the first support layer 340 may have a thickness of about 80 nm or more. In an example in which the first support layer 340 has a thickness of 500 nm or more, deviation in reflectance or color tone may occur, and thus the first support layer 340 may be formed to have a thickness of about 500 nm or less. According to an embodiment, a refractive index of the first support layer 340 may range from about 1.9 to about 2.05. For example, the refractive index of the first support layer 340 may be about 0.1 or more lower than the refractive index of the second material 332 of the color layer 330. For example, the first support layer 340 may include at least one of silicon nitride (SiN) and silicon oxynitride (SiON). For example, the first support layer 340 may be referred to as a first scratch-resistant layer.

According to an embodiment, referring to FIG. 5, the housing 300 may further include a second support layer 360 disposed on the reflective layer 350. For example, a thickness t4 of the second support layer 360 may range from about 80 nm to about 500 nm. For example, in order to provide hardness equal to or greater than the hardness of the substrate 310, the second support layer 360 may require a thickness of about 80 nm or more. In an example in which the second support layer 360 having a thickness of 500 nm or more is formed, deviation in reflectance or color tone may occur, and thus, in accordance with one or more embodiments of the present disclosure, the second support layer 360 may be formed to have a thickness of about 500 nm or less. According to an embodiment, a refractive index of the second support layer 360 may range from about 1.9 to about 2.05. For example, the refractive index of the second support layer 360 may be about 0.1 or more lower than the refractive index of the fourth material 352 of the reflective layer 350. For example, the second support layer 360 may include at least one of silicon nitride (SiN) and silicon oxynitride (SiON). For example, the second support layer 360 may be referred to as a second scratch-resistant layer. However, the second support layer 360 may be omitted according to an embodiment.

According to an embodiment, the housing 300 may further include a protective coating layer 370 disposed on the second support layer 360 and configured to protect the housing 300 from external contamination. The protective coating layer 370 may be configured to prevent or reduce contamination and to facilitate cleaning. For example, the protective coating layer 370 may be manufactured by a vapor deposition method. A refractive index of the protective coating layer 370 may range from about 1.0 to about 1.5. Preferably, the refractive index of the protective coating layer 370 may be about 1.3. However, the protective coating layer 370 may be omitted according to an embodiment.

According to an embodiment, the housing 300 may further include a capping layer (not illustrated) disposed between the second support layer 360 and the protective coating layer 370. The capping layer may be configured to address reflectance change or color variation caused by optical interference occurring due to an increased difference between the refractive index of the second support layer 360 and the refractive index of the protective coating layer 370. However, the capping layer may be omitted according to an embodiment.

According to an embodiment, the housing 300 may exhibit a Berkovich indenter hardness of about 12 GPa or more at a depth of about 100 nm. The housing 300 may exhibit a reflectance of about 10% or more. The housing 300 may exhibit a color shift within about a color coordinate value of 5 under conditions in which a scratch indentation depth is about 50 nm to about 150 nm or in which a coating thin film of the housing including the first support layer 340 and the second support layer 360 is damaged. For example, under a Mohs test condition (Mohs hardness 8, load of 1 kg, 10 scratches with an interval of 1 mm, and a scratch length of 20 mm), a color shift (ΔE_ab) value may be within 5 (measured by an integrating sphere type colorimeter SCI method).

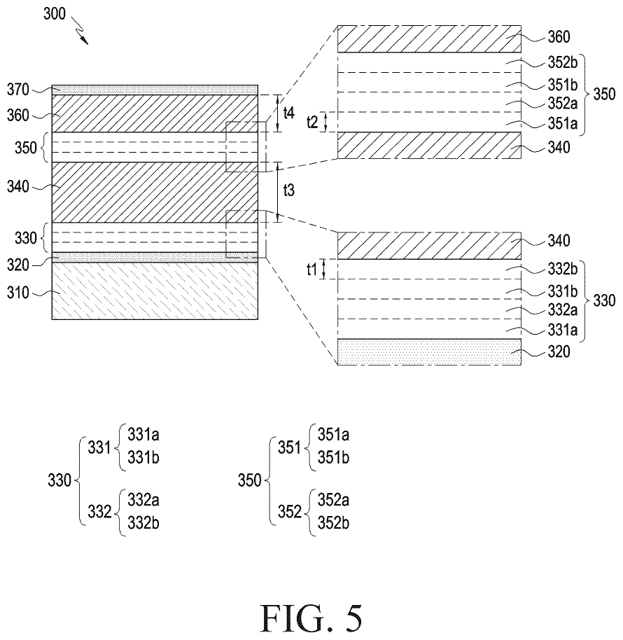

FIG. 6 is a cross-sectional view illustrating a portion of the housing 300, according to an embodiment disclosed herein.

Referring to FIG. 6, the housing 300 of the electronic device 101 may include a substrate 310, a buffer layer 320, a color layer 330, a first support layer 340, a reflective layer 350, and a protective coating layer 370. The configuration of the substrate 310, the buffer layer 320, the color layer 330, the first support layer 340, the reflective layer 350, and the protective coating layer 370 of the housing 300 in FIG. 6 may be wholly or partially the same as the configuration of the substrate 310, the buffer layer 320, the color layer 330, the first support layer 340, the reflective layer 350, and the protective coating layer 370 of the housing 300 in FIG. 5. The structure of FIG. 6 may be selectively combined with the structure of FIG. 5.

According to an embodiment, without disposing a support layer on the reflective layer 350, the thickness of the first support layer 340 disposed between the reflective layer 350 and the color layer 330 may be formed to be relatively thicker than the first support layer 340 of FIG. 5. The thickness of the first support layer 340 may be, for example, about 1000 nm to about 2000 nm or more. Even if a portion of the reflective layer 350 is lost due to external scratches, a change in reflectance may occur. However, since the color layer 330 is disposed at the lower side of the housing 300, that is, adjacent to the substrate 310, the degree of color variation due to scratches may be reduced.

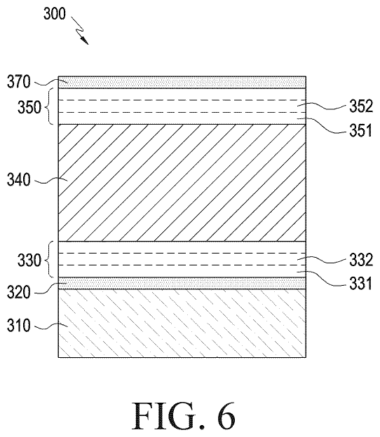

FIG. 7 illustrates a change in color shift due to scratches of the housing 300 according to an embodiment disclosed herein, under an abrasion resistance evaluation using steel wool.

The configuration of the housing 300 of FIG. 7 may be wholly or partially the same as the configuration of the housing 300 of FIGS. 5 to 6. The structure of FIG. 7 may be selectively combined with the structures of FIGS. 5 and 6.

According to an embodiment, in the abrasion resistance evaluation using steel wool, in a reference sample to which a general coating was applied, the glass surface was worn and a color change due to a texture difference appeared, and a variation in color shift at a level of 9.19 was observed as a portion of a capping layer and of a scratch-resistant layer were generally worn. Under the same test conditions, in the housing 300 according to an embodiment of the disclosure, as scratches caused wear, a variation in color shift at a level of 1.89 was observed. Thus, it may be identified that scratch visibility was reduced.

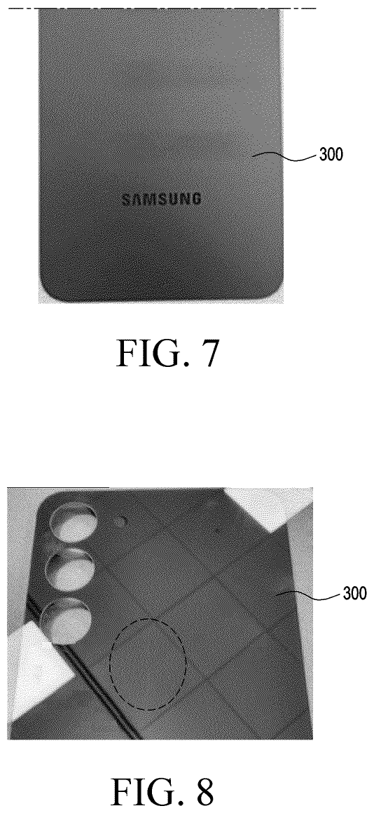

FIG. 8 illustrates scratch visibility of the housing 300 according to an embodiment disclosed herein, after a scratch test using a Mohs hardness tester, under a condition in which ambient light is reflected laterally.

The configuration of the housing 300 of FIG. 8 may be wholly or partially the same as the configuration of the housings 300 of FIGS. 5 to 7. The structure of FIG. 8 may be selectively combined with the structures of FIGS. 5 to 7.

According to an embodiment, in comparison with a general case in which a damaged portion is typically developed as a complementary color (opposite color) to the deposition reflection color, thereby causing a distinct color difference between a normal portion and a damaged portion, in the housing 300 according to the disclosure, it may be identified that the scratch pattern is diffused only when ambient light is strong, with substantially no color shift (see FIG. 8). Therefore, it may be identified that scratch visibility is reduced under the scratch test conditions.

In an electronic device including a housing 300 according to an embodiment of the disclosure, the housing 300 includes a substrate 310, a color layer 330 disposed above the substrate 310 wherein a first material 331 having a first refractive index and a second material 332 having a second refractive index greater than the first refractive index are alternately stacked, a first support layer 340 disposed on the color layer 330, and a reflective layer 350 disposed on the first support layer 340 wherein a third material 351 having a third refractive index and a fourth material 352 having a fourth refractive index greater than the third refractive index are alternately stacked. A difference between the first refractive index and the second refractive index is greater than a difference between the third refractive index and the fourth refractive index, and the third refractive index may be greater than the first refractive index.

According to an embodiment, the electronic device may further include a second support layer 360 disposed on the reflective layer 350.

According to an embodiment, a difference between the first refractive index and the second refractive index may be 0.5 or more.

According to an embodiment, a difference between the third refractive index and the fourth refractive index may be 0.3 or less.

According to an embodiment, a color coordinate value of the color layer 330 may be 5 or more.

According to an embodiment, the first refractive index may range from 1.4 to 1.6, and the second refractive index may range from 2.0 to 2.5.

According to an embodiment, the third refractive index may range from 1.65 to 2.0, and the fourth refractive index may range from 2.0 to 2.5.

According to an embodiment, the color layer 330 and the reflective layer 350 may be disposed so as to be physically separated from each other.

According to an embodiment, the electronic device may further include a buffer layer 320 disposed between the substrate 310 and the color layer 330 and configured to attach the substrate 310 and the color layer 330 to each other.

According to an embodiment, the housing 300 may further include a protective coating layer 370 disposed on the second support layer 360 and configured to protect the housing 300 from external contamination.

According to an embodiment, a reflectance of the reflective layer 350 may be 10% or more.

According to an embodiment, the color layer 330 may be disposed closer to the substrate 310 than the reflective layer 350.

In an electronic device including a housing 300 according to an embodiment of the disclosure, the housing 300 includes a substrate 310, a color layer 330 disposed on the substrate 310 wherein a first material 331 having a first refractive index and a second material 332 having a second refractive index greater than the first refractive index are alternately stacked, a first support layer 340 disposed on the color layer 330, and a reflective layer 350 disposed on the first support layer 340 wherein a third material 351 having a third refractive index and a fourth material 352 having a fourth refractive index greater than the third refractive index are alternately stacked. A color coordinate value of the color layer 330 may be 5 or more, and a reflectance of the reflective layer 350 may be 10% or more.

According to an embodiment, the electronic device may further include a second support layer 360 disposed on the reflective layer 350.

According to an embodiment, a difference between the first refractive index and the second refractive index may be 0.5 or less.

According to an embodiment, a difference between the third refractive index and the fourth refractive index may be 0.3 or less.

According to an embodiment, the first refractive index may range from 1.4 to 1.6, and the second refractive index may range from 2.0 to 2.5.

According to an embodiment, the third refractive index may range from 1.65 to 2.0, and the fourth refractive index may range from 2.0 to 2.5.

According to an embodiment, the color layer 330 and the reflective layer 350 may be disposed to be physically separated from each other.

According to an embodiment, the color layer 330 may be disposed closer to the substrate 310 than the reflective layer 350.

The technical problem to be solved by the disclosure is not limited to the technical problem mentioned above, and other technical problems not mentioned may be clearly understood by those ordinarily skilled in the art to which the disclosure pertains from the following description.

In general, by disposing an optical coating layer in which a high refractive index material and a low refractive index material are alternately stacked on the surface of the housing 300 substrate 310, a specific reflectance and color tone may be simultaneously implemented by utilizing an optical interference effect caused by a difference in refractive indices between the materials, and by disposing a high hardness layer on top of the optical coating layer, resistance to external scratches may be ensured. However, under an external pressure condition exceeding the hardness of the optical coating layer including the high hardness layer, color shift caused by damage to a portion of the optical coating layer due to external scratches may cause a color difference between an undamaged portion and a damaged portion of the coating layer, thereby making scratch visibility more noticeable.

The disclosure relates to a method of reducing scratch visibility in an optical coating having a specific color or reflectance on the surface of an outer housing 300 of a portable electronic device.

According to an embodiment of the disclosure, the color layer 330 may be disposed closer to the substrate 310 than the reflective layer 350. According to an embodiment, since the color layer 330 is disposed farther from an outer surface than the reflective layer 350, the possibility of damage due to scratches may be reduced. Even if a portion of the surface of the housing is lost due to scratches or wear, since the possibility of damage to the color layer 330 is low, color visibility due to scratches may be reduced.

In the disclosure, the color layer 330, which causes a scratch to become noticeable due to a change in color caused by scratch damage, is designed separately from the reflective layer 350, such that scratch visibility may be delayed and/or reduced.

The effects obtainable from the disclosure are not limited to those mentioned above, and other effects not mentioned may be clearly understood by those ordinarily skilled in the art to which the disclosure pertains from the following description.

What is claimed is

1. An electronic device comprising:
a housing comprising:
a substrate;
a color layer disposed above the substrate, wherein a first material having a first refractive index and a second material having a second refractive index greater than the first refractive index are alternately stacked in the color layer;
a first support layer disposed on the color layer; and
a reflective layer disposed on the first support layer, wherein a third material having a third refractive index and a fourth material having a fourth refractive index greater than the third refractive index are alternately stacked in the reflective layer,
wherein:
a difference between the first refractive index and the second refractive index is greater than a difference between the third refractive index and the fourth refractive index, and
the third refractive index is greater than the first refractive index.

2. The electronic device of claim 1, further comprising a second support layer disposed on the reflective layer.

3. The electronic device of claim 2, wherein the housing further comprises a protective coating layer disposed on the second support layer and which protects the housing from an external contamination.

4. The electronic device of claim 3, wherein the protective coating layer is visually exposed to an outside of the electronic device.

5. The electronic device of claim 1, wherein the difference between the first refractive index and the second refractive index is 0.5 or more.

6. The electronic device of claim 1, wherein the difference between the third refractive index and the fourth refractive index is 0.3 or less.

7. The electronic device of claim 1, wherein a color coordinate value of the color layer is 5 or more.

8. The electronic device of claim 1, wherein:
the first refractive index ranges from 1.4 to 1.6, and the second refractive index ranges from 2.0 to 2.5.

9. The electronic device of claim 1, wherein:
the third refractive index ranges from 1.65 to 2.0, and the fourth refractive index ranges from 2.0 to 2.5.

10. The electronic device of claim 1, wherein the color layer and the reflective layer are physically separate from each other.

11. The electronic device of claim 1, further comprising a buffer layer disposed between the substrate and the color layer and which attaches the substrate and the color layer.

12. The electronic device of claim 1, wherein a reflectivity of the reflective layer is 10% or more.

13. The electronic device of claim 1, wherein the color layer is disposed closer to the substrate than the reflective layer.

14. The electronic device of claim 1, wherein the color layer comprises:
a (1-1)^{th} material having the first refractive index;
a (2-1)^{th} material disposed on the (1-1)^{th} material and having the second refractive index;
a (1-2)^{th} material disposed on the (2-1)^{th} material and having the first refractive index; and
a (2-2)^{th} material disposed on the (1-2)^{th} material and having the second refractive index.

15. The electronic device of claim 1, wherein the reflective layer comprises:
a (3-1)^{th} material having the third refractive index;
a (4-1)^{th} material disposed on the (3-1)^{th} material and having the fourth refractive index;
a (3-2)^{th} material disposed on the (4-1)^{th} material and having the third refractive index; and
a (4-2)^{th} material disposed on the (3-2)^{th} material and having the fourth refractive index.
